(19) United States
(12) Patent Application Publication
(10) Pub. No.: US 2012/0169355 A1
(43) Pub. Date: Jul. 5, 2012

(54) SENSOR STRIP FOR OBSTACLE DETECTION AND CONNECTING STRUCTURE THEREOF

(75) Inventors: Seung-Won Cho, Gyeonggi-do (KR); Jung-Gi Oh, Gyeonggi-do (KR); Kwang-Seok Jeong, Gyeonggi-do (KR)

(73) Assignee: PULSETECH CO., LTD., Gyeonggi-do (KR)

(21) Appl. No.: 13/392,640

(22) PCT Filed: Jul. 22, 2011
(86) PCT No.: PCT/KR2011/005417

§ 371 Date: Mar. 23, 2012

(30) Foreign Application Priority Data
Sep. 30, 2010 (KR) 10-2010-0095165

(51) Int. Cl. G01R 27/26

(52) U.S. Cl. 324/658

(57) ABSTRACT

Provided is a sensor strip for detecting an obstacle using a change in electrostatic capacitor, comprising: a sensor body which is formed with a reference surface coupled to an object; and a plate type strip electrode of which a center portion is closer to the reference surface than a peripheral portion thereof with respect to a transverse direction.

### FIELD

The present invention relates to a sensor strip which is used in a system for detecting an obstacle using a change in electrostatic capacity, more particularly to a sensor strip which can reduce a risk of malfunction by using a plate type strip electrode curved in one direction.

### BACKGROUND

In most conventional automobiles, a door is manually switched on and off, but is recently being manufactured to be automatically switched on and off.

Therefore, in order to prevent a safety accident to any part of the human body, such as hands, being caught in the door or window, a system for detecting an obstacle is required to stop the operation of the door or window when the obstacle is detected.

The system for detecting an obstacle can be classified into a contact type and a non-contact type. The contact type system determines whether the obstacle exists by detecting a change of air pressure or electric load due to contact with the obstacle, and the non-contact type system determines whether the obstacle exists before the obstacle is contacted with the door or window, for example, by using a change in electrostatic capacity.

FIG. 1 shows a schematic view of a conventional system for detecting an obstacle using a change in electrostatic capacity. The system for detecting an obstacle includes an electrostatic capacity detecting module 12 for detecting the electrostatic capacity, a control module 18 which determines whether the obstacle exists using a signal output from the electrostatic capacity detecting module 12, and a cable 20 which transfers the output signal from the electrostatic capacity detecting module 12 to the control module 18.

The electrostatic capacity detecting module 12 includes at least one or more sensor strips 14 which are disposed along the periphery of the door or window, and an electrostatic capacity detecting circuit 16 which is coupled to an end of each sensor strip 14.

The control module 18 compares an output signal of the electrostatic capacity detecting circuit 16 with a standard value. And if the output signal is out of a permissible range, the control module 18 determines that the obstacle is close and transfers a control signal to an opening/closing module 30 for automatically switching on and off the door or window so as to stop the operation of the door or window or operate it in an opposite direction.

Meanwhile, a conventional sensor strip 14 as shown in FIG. 2 has the configuration that a cavity 43 is formed longitudinally in a sensor body 41 formed of a rubber material having excellent flexibility and first and second electrodes 42 and 44 are disposed at upper and lower sides of the cavity 43 so as to be opposed to each other. In case that a reference surface 45 of the sensor strip 14 is directly attached to a vehicle body, the second electrode 44 may be omitted because the vehicle body itself functions as the electrode.

The electrostatic capacity detecting circuit 16 is connected to the sensor strip 14. The electrostatic capacity detecting circuit 16 is inserted into the cavity 43 of the sensor strip 14 while being mounted on a PCB substrate and then molded with a rubber material so as to be integrally formed with the sensor strip 14.

A desired electrostatic capacity is formed between the first and second electrodes 42 and 44. The electrostatic capacity is changed when an obstacle comes close from an outside. Therefore, by detecting a change in the electrostatic capacity, it can be determined whether the obstacle comes close.

However, in the conventional sensor strip 14, there are some problems as follows:

First, the convention first and second electrodes 42 and 44 have a metal mesh structure that is woven from metal threads. Thus, the electrode becomes thick and also the manufacturing cost is increased.

Second, if the electrode becomes thick, the electrostatic capacity may be easily changed by an obstacle which comes close from a lateral direction, and thus the closing operation of the window can be often interrupted.

More detailedly, as shown in FIG. 3, in case that the sensor strip 14 is disposed at the periphery of a vehicle body 50, i.e., the periphery of a packing portion 52 in which an upper end of the window 60 is inserted, if the thickness of the electrode 42, 44 is so thick, lateral sensitivity is increased and thus the electrostatic capacity may be changed by the window 60 which is moving up and down at the side of the sensor strip 14. Therefore, the control module 18 misjudges the situation that the obstacle comes close, and stops the operation of the window 60.

In order to prevent the misjudgment, it is necessary that the sensor strip 14 is disposed to be sufficiently spaced apart from an end of the vehicle body 50. However, it is very difficult to secure the necessary area from the vehicle body 50.

Further, the lateral sensitivity can be somewhat reduced by reducing a width of the electrode 42, 44. However, in this case, since overall sensitivity is also reduced, the actual obstacle may be not detected.

Third, as described above, in order to connect the PCB substrate, on which the electrostatic capacity detecting circuit 16 is mounted, to the end of the sensor strip 14, it is necessary that the PCB substrate is inserted into the cavity 43 formed in the sensor strip 14 and then the molding process using the rubber material should be carried out. However, since the molding liquid may be introduced into the cavity 43 during the molding, it is difficult to perform the molding process.

Fourth, in case of the sensor strip 14 disposed about a side window of a vehicle, it is necessary to reduce the lateral sensitivity. However, in case of a side door or rear door which is automatically opened and closed, it is necessary to entirely expand the detection range. But in the conventional sensor strip 14, it is not possible to increase the detection range without increasing the width of the electrode. Further, considering an installation area of the sensor strip 14 is restricted, the increasing of the width of the electrode is also limited.

### DETAILED DESCRIPTION

### Technical Problem

An embodiment of the present invention is directed to providing a sensor strip which can be simply manufactured with low cost and also can reduce a risk of malfunction.

### Technical Solution

To achieve the object of the present invention, the present invention provides a sensor strip that includes a sensor body, which is formed with a reference surface coupled to an object; and a plate type strip electrode which is longitudinally buried in the sensor body and of which a center portion is closer to the reference surface than a peripheral portion thereof with respect to a transverse direction.

In the sensor strip of the present invention, the strip electrode has a curved shape in section with respect to a transverse direction thereof, or a V-shape in section, which is symmetric with respect to the center portion and also inclined with respect to the reference surface.

Preferably, the strip electrode includes first and second strip electrodes which are parallelly spaced apart from each other.

Further, the present invention provides a sensor strip includes a sensor body which is formed with a reference surface coupled to an object; and a plate type strip electrode which is longitudinally buried in the sensor body and of which a center portion is further spaced apart from the reference surface than a peripheral portion thereof with respect to a transverse direction.

Further, the present invention provides a sensor strip for obstacle detection, including a sensor body which is formed with a reference surface coupled to an object, and formed with no cavity, and also formed with a insertion groove formed at an end thereof; a strip electrode which is longitudinally buried in the sensor body; a PCB substrate on which an electrostatic capacity detecting circuit electrically connected with the strip electrode is mounted; a conductive protection case which is provided at the PCB substrate to cover the electrostatic capacity detecting circuit and connected with a ground terminal of the PCB substrate; and a molding portion which is formed to cover the PCB substrate and the conductive protection case in a state that at least part of the PCB substrate is inserted into the insertion groove of the sensor body, thereby integrally forming the PCB substrate with the sensor body.

Preferably, the conductive protection case is connected with a ground member which is extended to an outside of the molding portion and coupled to a vehicle body. Further, the present invention provides a connecting structure of the sensor strip, wherein the strip electrode comprises first and second strip electrodes which are disposed to be parallel with each other, and the first strip electrode is connected with a connection terminal formed at the PCB substrate in the molding portion, and the second strip electrode is protruded to the outside of the molding portion so as to be coupled to a vehicle body or is electrically connected to the conductive protection case in the molding portion.

Further, the present invention provides a connecting structure of the sensor strip, wherein the sensor body is formed with a coupling protrusion or coupling groove which is formed longitudinally, and a carrier having a coupling protrusion or coupling groove corresponding to the coupling protrusion or coupling groove of the sensor body is installed at a detection area, and the sensor body is slidably coupled with the carrier.

### Advantageous Effect

According to one embodiment of the present invention, since the detection area of the sensor strip is concentrated to the center portion, it is possible to reduce the lateral sensitivity, and thus it is possible to solve the problem of interrupting the operation of the window due to the misjudgment of the up/down movement of the window.

Further, since the strip electrode is formed of the thin metal plate, it is possible to reduce the manufacturing cost. And since the sensor body is not formed with the cavity, the molding process can be performed facilely.

Further, according to another embodiment of the present invention, since the detection area of the sensor strip becomes wider, it is possible to improve the accuracy of detecting the obstacle at the side door or rear door.

### DESCRIPTION OF DRAWINGS

FIG. 1 is a schematic view of a system for detecting an obstacle using a change in electrostatic capacity.

FIG. 2 is a cross-sectional view of a conventional sensor strip.

FIG. 3 is a view showing that a sensor strip is disposed about a window of a vehicle.

FIG. 4 is a cross-sectional view of a sensor strip according to a first embodiment of the present invention.

FIG. 5 is a cross-sectional view showing a modified example of the sensor strip according to the first embodiment of the present invention.

FIG. 6 is a cross-sectional view showing that the sensor strip according to the first embodiment is installed at a carrier.

FIG. 7 is a cross-sectional view showing a coupling structure of a sensor strip with two built-in strip electrodes.

FIG. 8 is a cross-sectional view showing a coupling structure of a sensor strip with one built-in strip electrode.

FIG. 9 is a cross-sectional view of a sensor strip according to a second embodiment of the present invention.

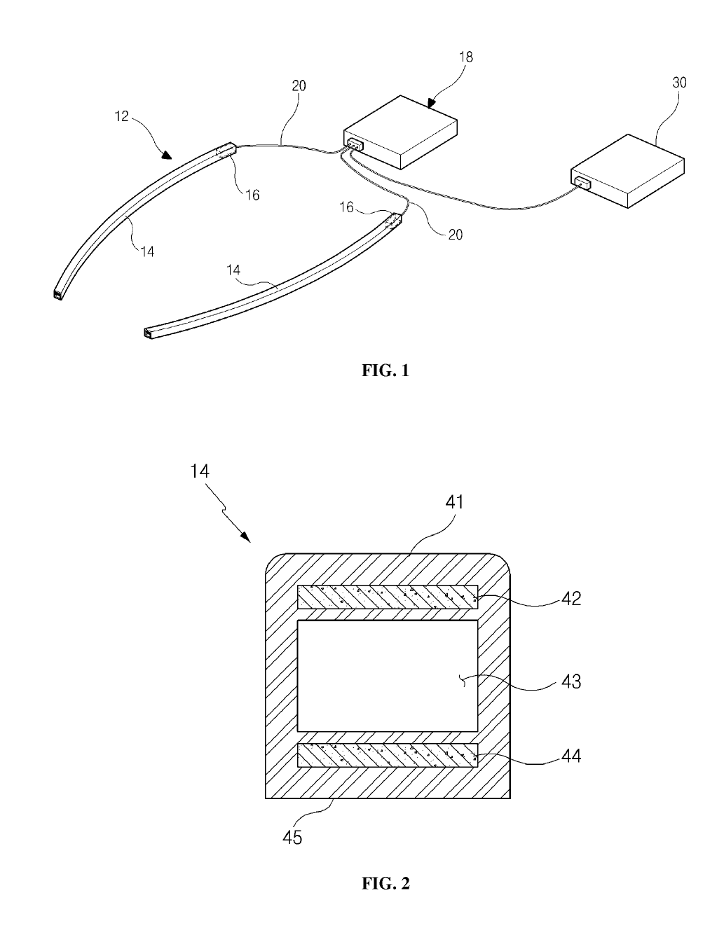

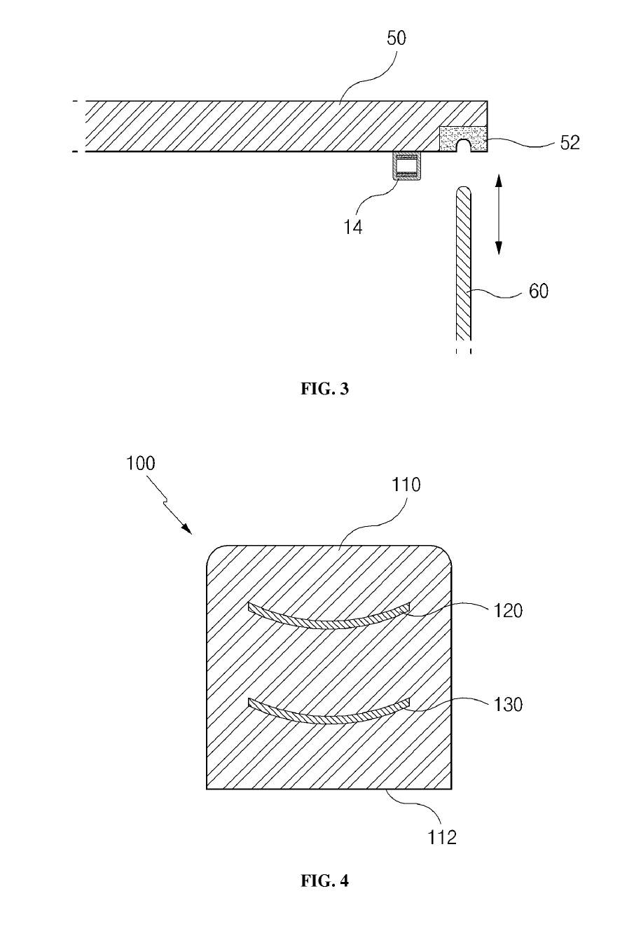

DETAILED DESCRIPTION OF MAIN ELEMENTS

| | |
|---|---|
| 100: sensor strip | 110: sensor body |
| 112: reference surface | 114: coupling groove |
| 116: insertion groove | 120: first strip electrode |
| 130: second strip electrode | 140: molding portion |
| 150: PCB substrate | 152: connection terminal |
| 160: conductive protection case | |
| 162: ground member | 170: cable |
| 200: carrier | 210: coupling protrusion |

### BEST MODE

Hereinafter, the embodiments of the present invention will be described in detail with reference to accompanying drawings.

### First Embodiment

As shown in FIG. 4, a sensor strip 100 according to a first embodiment of the present invention includes a sensor body 110 formed into a strip type having a rectangular shape in section, and first and second strip electrodes 120 and 130 which are longitudinally buried in the sensor body 110 so as to be opposed to each other.

Preferably, the sensor body 110 is formed of a flexible material such as rubber, and formed with no cavity. However, the sensor body 110 formed of a hard material which is not bent easily may be used according to an installation position thereof.

Hereinafter, for convenience of explanation, a surface of the sensor body 110 which is coupled to a vehicle body or a carrier 200 to be described later will be called as a reference surface.

According to the present invention, the first and second strip electrodes 120 and 130 are formed of a thin plate type metal strip having a width of about 4 to 5 mm and a thickness of about 0.2 mm in order to reduce lateral sensitivity.

Particularly, in the first embodiment of the present invention, center portions of the first and second strip electrodes 120 and 130 are closer to the reference surface 112 than peripheral portions thereof with respect to a transverse direction. For example, as shown in FIG. 4, when the first and second strip electrodes 120 and 130 have a concave shape in section with respect to the reference surface 112, a detection area is concentrated to center axes of the first and second strip electrodes 120 and 130, thereby reducing the lateral sensitivity.

Preferably, each strip electrode 120, 130 having a width of 4 mm has a circumferential diameter of about 2 to 3 cm.

For convenience in manufacturing, as shown in FIG. 5, each strip electrode 120, 130 may have a V-shape in section, instead of a curved shape. In this case, inclined surfaces between a center portion and both side ends are formed to be flat.

Preferably, a distance between the both side ends of each strip electrode 120, 130 is 4 to 5 mm and also the center portion is worked into a curved shape in order to prevent an electric charge from being concentrated to the sharp center portion.

In FIGS. 4 and 5, the two strip electrodes 120 and 130 are buried in the sensor body 110. However, in case that the sensor strip is directly attached to a vehicle body formed of a metallic material, the second strip electrode 130 which is close to the reference surface 112 may be omitted. In this case, the vehicle body functions as the second strip electrode opposed to the first strip electrode 120.

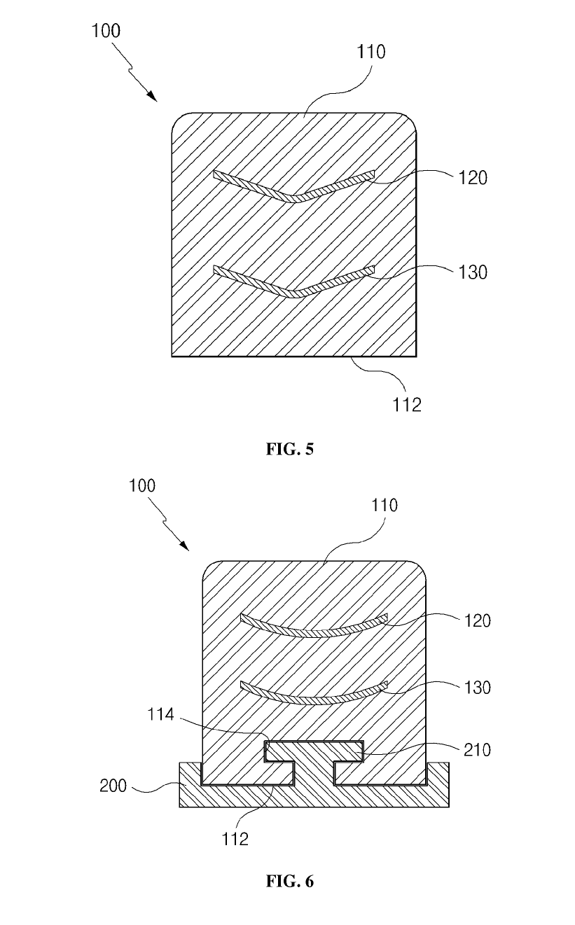

Meanwhile, the sensor strip 100 may be directly attached to the vehicle body, but in order to easily replace it with new one, as shown in FIG. 6, it is preferable that a carrier 200 is attached to the vehicle body and then the sensor strip 100 is installed on the carrier 200.

In case of using the carrier 200, a coupling groove 114 is longitudinally formed in the reference surface 112 of the sensor body 110, and a coupling protrusion 210 corresponding to the coupling groove 114 is longitudinally formed in the carrier 200.

An inner space of the coupling groove 114 is wider than an entrance thereof, and the coupling protrusion 210 is configured to be mated with the coupling groove 114. Therefore, in the state that the carrier 200 is attached to the vehicle body, the coupling protrusion 210 of the carrier 200 is inserted into the coupling groove 114 of the sensor strip 100 from an end of the carrier 200 and then pushed therein. Therefore the sensor strip 100 can be facilely installed and easily disassembled.

In the other way, the coupling groove may be formed in the carrier 200 and the coupling protrusion corresponding to the coupling groove may be formed in the sensor body 110.

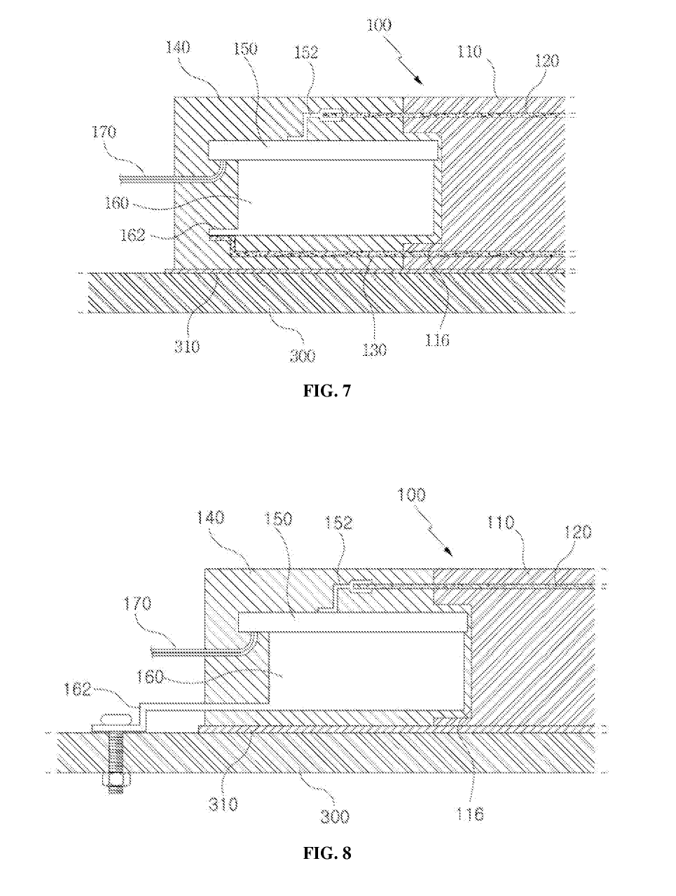

As shown in FIG. 7, in the sensor strip 100 according to the first embodiment of the present invention, an insertion groove 116 is formed at an end thereof, and an end of a PCB substrate 150 on which an electrostatic capacity detecting circuit is mounted is inserted into the insertion groove 116 and then a rubber material is molded thereon, whereby the sensor strip 100 is integrally formed with the PCB substrate 150. The PCB substrate 150 may be partially or wholly inserted into the insertion groove 116.

Herein, as shown in the drawing, a conductive protection case 160 formed of a metallic material may be provided at the PCB substrate 150 to cover and protect the electrostatic capacity detecting circuit and also to prevent influence of electromagnetic waves.

More detailedly, the first strip electrode 120 which is protruded to an end of the sensor body 110 is connected to a connection terminal 152 formed at the PCB substrate 150, and a ground terminal (not shown) formed at the PCB substrate 150 is electrically connected with the conductive protection case 160. Further, a ground member 162 is formed at the conductive protection case 160 and then connected to the second strip electrode 130, whereby the ground terminal of the PCB substrate 150 can be electrically connected with the second strip electrode 130.

A molding portion 140 for integrally forming the PCB substrate 150 and the sensor body 110 is formed so as to cover all of the PCB substrate 150 and the conductive protection case 160 in the state that the first strip electrode 120 is connected with the connection terminal 152.

Meanwhile, FIG. 7 shows that the ends of the second strip electrode 130 and the ground member 160 are connected with each other in the molding portion 140, but the present invention is not limited to this. That is, the ends of the second strip electrode 130 and the ground member 160 may be exposed to an outside of the molding portion 140 and then may be coupled to the vehicle body 300 by using a bolt or the like.

A cable 170 for connecting an external control module and the electrostatic capacity detecting circuit mounted on the PCB substrate 150 is extended from an end of the molding portion 140 to an outside. Further even though not shown in the drawings, a transfer line for transferring a detection signal generated from the electrostatic capacity detecting circuit to the external control module is also extended to the outside. However, in case that the detection signal is transferred in a wireless manner, the transfer line may be omitted.

The sensor strip 100 which is integrally formed with the PCB substrate 150 is attached to the vehicle body 300 using an adhesive. Otherwise, the sensor strip 100 may be coupled to the carrier 200, as described above.

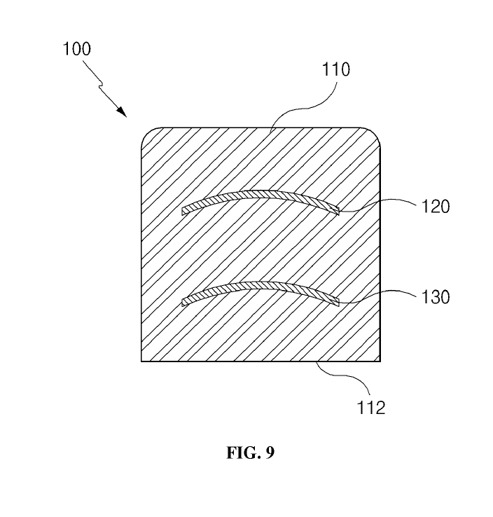

Meanwhile, if the vehicle body 300 is formed of a conductive material, it functions as the second strip electrode. In this case, as shown in FIG. 8, the sensor strip 100 with only the first strip electrode 120 is used and the ground member 160 of the conductive protection case 160, which is exposed to the outside, is coupled to the vehicle body 300.

### Second Embodiment

The sensor strip 100 according to the first embodiment of the present invention is mainly to control a side window of a vehicle. Thus, the sensor strip 100 is proposed to reduce the lateral sensitivity so that the window which is moved up and down is not recognized as the obstacle.

However, since the sensor strip 100 installed at the window functions to detect only whether the obstacle exists in a lifting area of the window, it is fine that the detection area becomes relatively narrow. However, the sensor strip 100 which is installed at the periphery of a side door or rear door should have a wider detection area. For example, when loading and unloading the vehicle in the state that a rear door or truck door is opened, a user may be located at various positions and thus the sensor strip 100 has to exactly detect the situation.

FIG. 9 shows a sensor strip 100 according to a second embodiment of the present invention. Like in the first embodiment, the sensor strip 100 includes a sensor body 110 formed into a strip type having a rectangular shape in section, first and second strip electrodes 120 and 130 which are longitudinally buried in the sensor body 110 so as to be opposed to each other.

However, in the second embodiment of the present invention, center portions of the first and second strip electrodes 120 and 130 are further spaced apart from the reference surface 112 than peripheral portions thereof with respect to a transverse direction. That is, as shown in FIG. 9, when the first and second strip electrodes 120 and 130 have a convex shape in section with respect to the reference surface 112, the detection area becomes wide to the peripheral portions of the first and second strip electrodes 120 and 130.

In this case, each strip electrode 120, 130 may be manufactured so that the center portion thereof has a reversed-V-shape in section. The curvature of each strip electrode 120, 130, the material of the sensor body 110, the coupling manner with the PCB substrate and the like are the same as in the first embodiment, and thus description thereof will be omitted.

Since the first and second strip electrodes 120 and 130 of the sensor strip 100 in the first embodiment and the first and second strip electrodes 120 and 130 of the sensor strip 100 in the second embodiment have an opposed curvature to each other, one product can be used in the window and also can be turned upside down so as to be used in the door.

Meanwhile, although it is explained that the sensor strip 100 of the present invention is installed at the vehicle, the application thereof is not limited to the vehicle because the sensor strip 100 is used in the window or door which is automatically opened and closed.

While the present invention has been described with respect to the specific embodiments, it will be apparent to those skilled in the art that various changes and modifications may be made without departing from the spirit and scope of the invention as defined in the following claims.

1. A sensor strip for obstacle detection, comprising:
a sensor body having a reference surface coupled to an object and an insertion groove formed at an end thereof;
a strip electrode which is longitudinally buried in the sensor body;
a PCB substrate;
an electrostatic capacity detecting circuit mounted on the PCB substrate which is electrically connected with the strip electrode;
a conductive protection case provided at the PCB substrate to cover the electrostatic capacity detecting circuit and connected with a ground terminal of the PCB substrate; and
a molding portion configured to cover the PCB substrate and the conductive protection case in a manner that at least part of the PCB substrate is inserted into the insertion groove of the sensor body.

2. The sensor strip of claim 1, wherein the strip electrode is formed of a metal plate.

3. The sensor strip of claim 1, wherein the conductive protection case is connected with a ground member which is extended to an outside of the molding portion and coupled to a vehicle body.

4. The sensor strip of claim 1, wherein the strip electrode comprises first and second strip electrodes which are disposed to be parallel with each other.

5. The sensor strip of claim 1, wherein the sensor body comprises a coupling protrusion or coupling groove which is formed longitudinally.

6. The sensor strip of claim 1, wherein the sensor body is formed so as not to have cavity.

7. The sensor strip of claim 1, wherein at least part of the PCB substrate is inserted into the insertion groove of the sensor body in a manner that the PCB substrate and the sensor body form an integral assembly.

8. The sensor strip of claim 1, wherein the strip electrode comprises first and second strip electrodes which are disposed to be parallel with each other, and
wherein the first strip electrode is connected with a connection terminal formed at the PCB substrate in the molding portion, and the second strip electrode is protruded to the outside of the molding portion so as to be electrically connected to the conductive protection case in the molding portion.

9. The sensor strip of claim 2, wherein a center portion of the strip electrode is closer to or further spaced apart from the reference surface than a peripheral portion thereof with respect to a transverse direction.

10. The sensor strip of claim 4, wherein the first strip electrode is connected with a connection terminal formed at the PCB substrate in the molding portion, and
wherein the second strip electrode is protruded to the outside of the molding portion so as to be coupled to a vehicle body

11. The sensor strip of claim 5, wherein a carrier having a coupling groove or coupling protrusion corresponding to the coupling protrusion or coupling groove of the sensor body is installed at a detection area

12. The sensor strip of claim 11, wherein the sensor body is slidably coupled with the carrier.
